(19) United States
(12) Patent Application Publication
(10) Pub. No.: US 2008/0122116 A1
(43) Pub. Date: May 29, 2008

(54) METHOD OF FORMING METAL LAYER WIRING STRUCTURE ON BACKSIDE OF WAFER, METAL LAYER WIRING STRUCTURE FORMED USING THE METHOD, METHOD OF STACKING CHIP PACKAGE, AND CHIP PACKAGE STACK STRUCTURE FORMED USING THE METHOD

(75) Inventors: Myeong-Soon PARK, Seoul (KR); In-Young LEE, Gyeonggi-do (KR); Ho-Jin LEE, Seoul (KR); Yong-Tae OH, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/942,529

(22) Filed: Nov. 19, 2007

(30) Foreign Application Priority Data
Nov. 23, 2006 (KR) 2006-0116582

(51) Int. Cl. H01L 21/58; H01L 23/522

(52) U.S. Cl. 257/777; 438/109; 257/E21.499; 257/E23.141

(57) ABSTRACT

Provided are a method of forming a metal layer wiring structure on the backside of a wafer, a metal layer wiring structure formed using the method, a method of stacking a chip package, and a chip package stack structure formed using the method. The method of stacking a chip package includes: forming recess patterns on a backside of wafers; forming a passivation layer on the backside of the wafers except for an area corresponding to a through electrode; forming a metal layer on the passivation layer; planarizing the metal layers to expose only the recess patterns; forming a lower insulating layer on the planarized metal layers except for an area corresponding to a contact portion with another wafer; forming an adhesive layer on the lower insulating layer of each of the wafers; and adhering the wafers to one another, wherein the recess patterns are formed using a laser.

### CROSS-REFERENCE TO RELATED PATENT APPLICATION

This application claims priority under 35 USC § 119 to Korean Patent Application No. 10-2006-0116582, filed on Nov. 23, 2006, in the Korean Intellectual Property Office, the disclosure of which is incorporated herein in its entirety by reference.

### BACKGROUND

1. Technical Field

The present invention relates to a chip package stack structure, and more particularly, to a method of forming a metal layer wiring structure and a method of stacking a chip package using the method of forming the metal layer wiring structure, in which a metal layer wiring structure is formed in a recess portion of a wafer using a laser.

2. Description of the Related Art

FIGS. 1A and 1B illustrate a conventional process of forming a metal layer wiring structure on the backside of a wafer.

Referring to FIGS. 1A and 1B, a passivation layer 102 is deposited on the backside of a wafer substrate 103. In operation (a), the passivation layer 102 is removed, using a conventional method such as etching, from a portion OP 1 corresponding to a through electrode 107. The passivation layer 102 is removed using a conventional method such as etching.

In FIGS. 1A and 1B, the backside of the wafer substrate 103 is shown in the upper portion.

Then, in operation (b), before an electroplating is performed, a seed layer 101 is deposited so that electroplating can be uniformly performed across the wafer substrate 103 without having an uneven structure. The seed layer 101 is uniformly deposited on the passivation layer 102 and the first open region OP1.

In operation (c), a photoresist 111 is coated on the seed layer 101. The photoresist 111 is a photo-sensitive material and a portion of the photoresist 111 is removed in operation (d). Although not illustrated in the drawings, the photoresist 111 is removed through various operations such as soft baking, alignment and exposure, developing, and hard baking. Thus, using the photoresist 111 requires all of the above described operations. The seed layer 101 is exposed in a portion where the photoresist 111 is removed. In operation (e), a metal layer 121, which will be used as a signal line, is formed on the exposed seed layer 101 by electroplating using an electrolysis plating or an A1 reflow method.

In operation (f), the remaining photoresist 111 is removed and the seed layer 101 disposed under the photoresist 111 is etched.

Then, in operation (g), the passivation layer 102 that is exposed after etching and the metal layer 121 are coated with an insulating material, such as a polymer, to form an insulating layer 131. The insulating layer 131 is formed on the passivation layer 102 and the metal layer 121 except for an area OP2 where the conventional wafer will be in electrical contact with a neighboring wafer. The insulating layer 131 is formed using an insulating forming method such as a spin coating method or a laminating method. The insulating layer 131 has a varying thickness due to the other structures on the backside of the wafer. Thus, the portion of the insulating layer 131 formed on the metal layer 121 is higher than the portion of the insulating layer 131 formed on the passivation layer 102. That is, the backside structure of the wafer illustrated in FIGS. 1A and 1B is not completely planar, but instead has some curvature.

FIG. 2 illustrates a chip package stack 200 including a plurality of wafers formed as described with respect to FIGS. 1A and 1B.

Referring to FIG. 2, a chip package 200 is formed of a plurality of wafers as illustrated in FIGS. 1A and 1B that are stacked.

When wafers are adhered to one another to form a chip package 200, an adhesive layer 201 needs to be provided between the wafers. The adhesive layer 201 is formed on the insulating layer 131, which is formed as shown in FIGS. 1A and 1B, to a predetermined thickness. The adhesive layer 201 is formed along the curvature of the lower layer of the insulating layer 131. FIG. 2 illustrates a cross-section of the stacked chip package 200. Although the through electrode 107 is not illustrated in FIG. 2, one of ordinary skill in the art would appreciate that the through electrode 107 could be seen when the cross-section of the chip package 200 is extended to the right and to the left.

As described with reference to FIGS. 1A and 1B, the metal layer wiring structure on the backside of the conventional wafer is formed using a bottom-up method, and thus an uneven wiring layer is formed. Since the insulating layer 131 has a predetermined curvature, the adhesive layer 201 also has a predetermined curvature, thereby forming an uneven wiring. In this case, the adhesive layer 201 has voids 231, and thus areas which do not make contact between the wafers will occur, and therefore the through electrode 211 may not contact one of the wafers. Accordingly, electrical conductivity is decreased, thereby decreasing the reliability of the chip package 200. As described above, the conventional metal wiring and the method thereof have problems such as a decrease in electrical conductivity and reliability due to contact defects.

In addition, as described with reference to FIGS. 1A and 1B, in the conventional wiring structure and method of forming the same, the photoresist 111 is used, which requires a photo-lithography process. The photolithography process includes photoresist coating, soft baking, alignment and exposure, developing, and hard baking. Accordingly, the manufacturing time is increased, and since the photolithography process is performed using expensive equipment, the manufacturing costs are also increased.

The present invention addresses these and other disadvantages of the conventional art.

### SUMMARY

Embodiments of the present invention provide a method of forming a wiring structure on a backside of a wafer and a wiring structure formed using the same, in which a photolithography process is not performed and laser patterning is performed. According to embodiments of the present invention the occurrence of voids in the conductive layer structure is minimized and the manufacturing process is simplified so as to reduce the manufacturing costs. Embodiments of the present invention also provide a method of stacking a chip package and a chip package stack structure formed using the method.

### BRIEF DESCRIPTION OF THE DRAWINGS

The above and other features and advantages of the present invention will become more apparent by describing in detail exemplary embodiments thereof with reference to the attached drawings in which:

FIG. 1A is a schematic view illustrating a conventional method of forming a metal layer wiring structure on a backside of a wafer;

FIG. 1B further illustrates the conventional method of FIG. 1;

FIG. 2 illustrates a chip package stack including a plurality of wafers formed as illustrated in FIGS. 1A and 1B;

FIG. 3A illustrates a method of forming a metal layer wiring structure on a backside of a wafer according to an embodiment of the present invention;

FIG. 3B further illustrates the method of FIG. 3A according to an embodiment of the present invention;

FIG. 3C is a flowchart of the method of FIG. 3A according to an embodiment of the present invention;

FIG. 4 is an image showing a recess pattern formed using a laser in the method of FIG. 3; and

FIG. 5 illustrates a chip package stack including a plurality of wafers formed according to the method of FIG. 3, according to an embodiment of the present invention.

### DETAILED DESCRIPTION

The present invention will now be described more fully with reference to the accompanying drawings, in which exemplary embodiments of the invention are shown. Like reference numerals denote like elements.

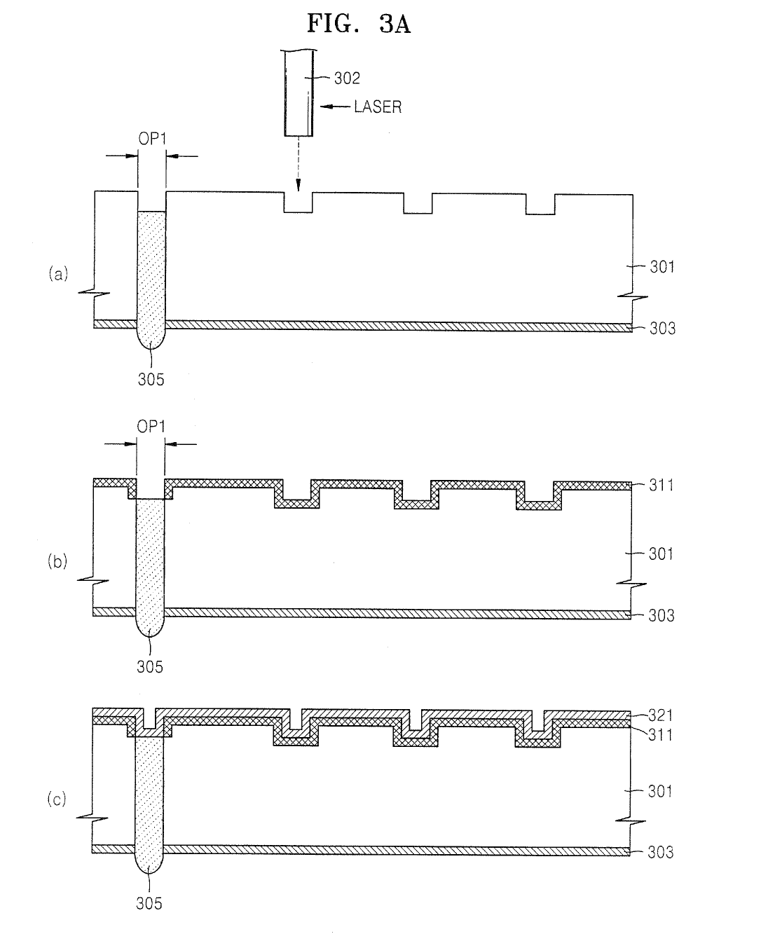

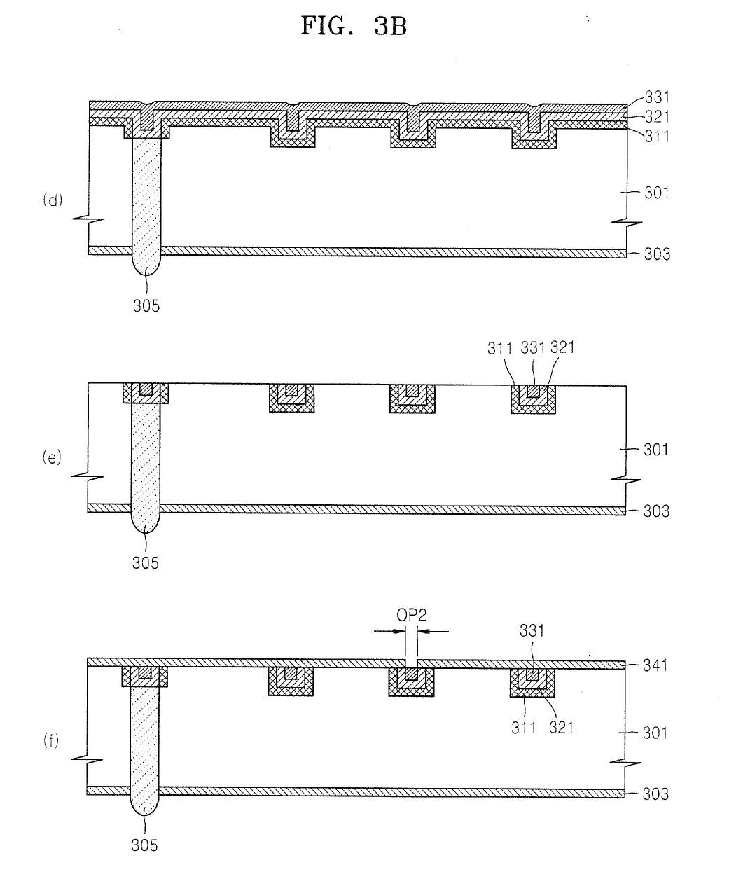

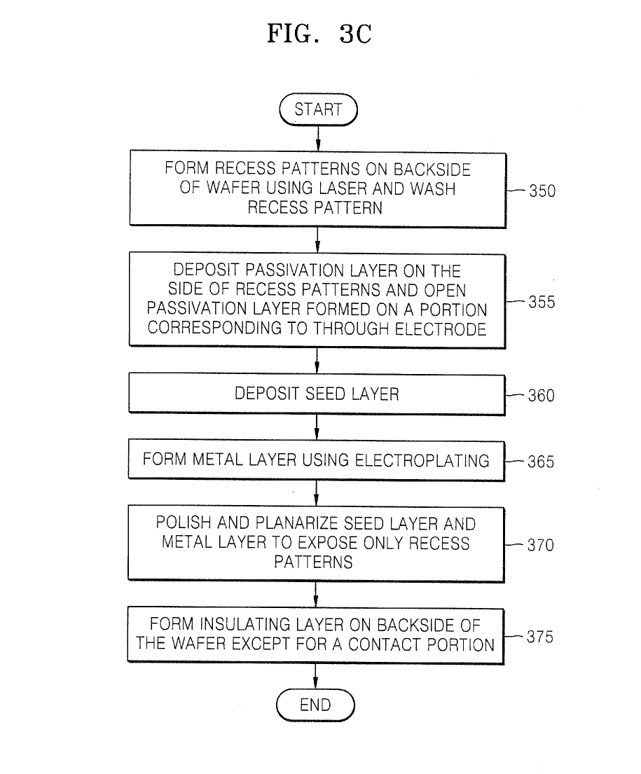

FIGS. 3A and 3B illustrate a method of forming a metal layer wiring structure on the backside of a wafer substrate 301 according to an embodiment of the present invention; and FIG. 3C is a flowchart of the method of FIGS. 3A and 3B, according to an embodiment of the present invention.

In FIGS. 3A and 3B the backside of the wafer substrate 301 is shown as the upper part of the wafer substrate 301. The method of FIGS. 3A and 3B will be explained in conjunction with the flowchart of FIG. 3C.

Referring to FIGS. 3A, 3B, and 3C, the backside of the wafer substrate 301 is etched using a laser 302 to form a plurality of recess patterns 304.

The number and position of the recess patterns 304 depend on the position of a through electrode of another wafer substrate that will be stacked on the wafer substrate 301. When identical chips are stacked and thus the position of the through electrodes is the same, recess patterns may be formed only on the position where the through electrodes are positioned.

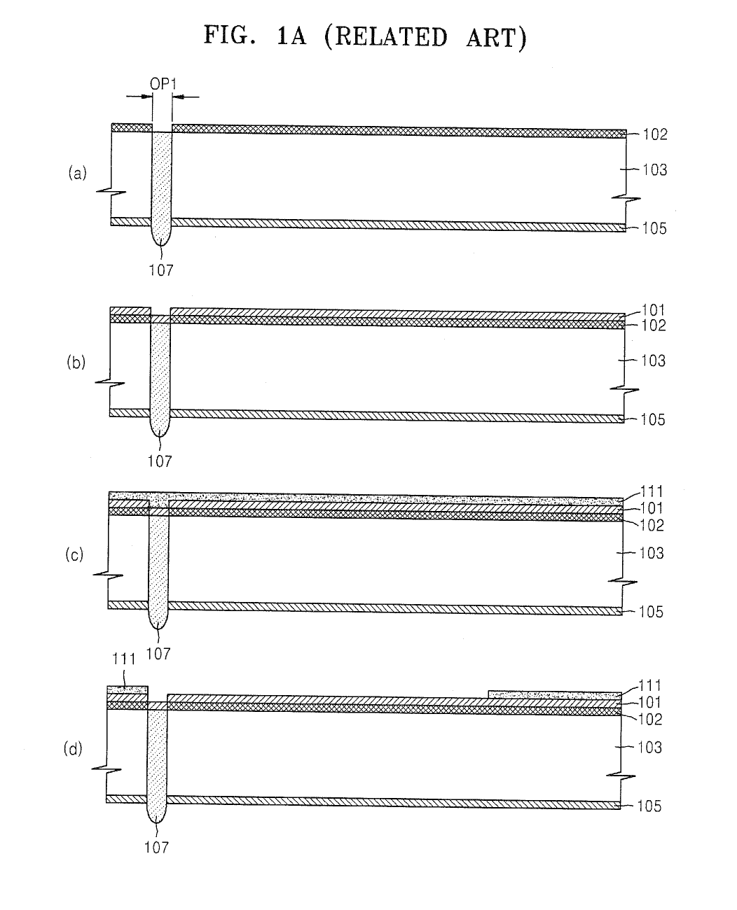

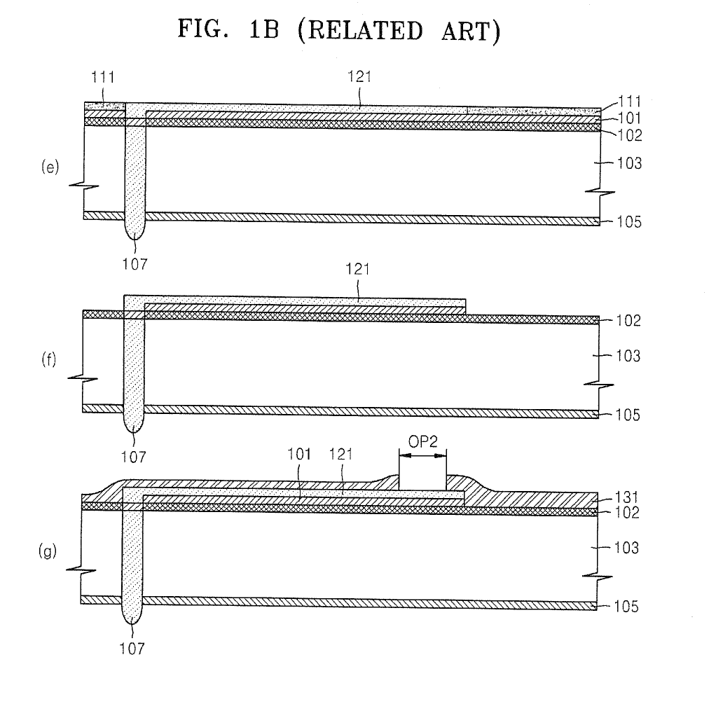

When a pattern is formed using laser 302, a lithography process in which etching is performed using a mask described with reference to the conventional art of FIGS. 1A and 1B can be omitted. As described above, a lithography process includes various operations and requires expensive equipment. In contrast, a pattern is formed using a laser according to the current embodiment of the present invention, and thus no expensive lithography equipment is needed, and the number of processes can be reduced.

A passivation layer 311 is deposited on the backside of the wafer in which the recess patterns 304 are formed (operation 355). The passivation layer 311 may include an upper layer of the passivation layer 311 and a lower layer of the passivation layer 311 on the backside of the wafer. That is, an insulating layer formed of SiNx, SiOx, etc., may be coated on the backside of the wafer in order to prevent current leakage. The passivation layer 311 is formed using a conventional method on the entire surface of the backside of the wafer except for an area OP1 where the through electrode 305 is positioned. The reason that the area OP1 is not covered is to allow a metal line wiring for the through electrode 305 of the wafer 301 to be connected to a through electrode of a neighboring wafer (not shown).

Then, in operation 360, a seed layer 321 is deposited on the passivation layer 311, including the area OP1. The seed layer 321 is uniformly deposited by performing uniform electroplating. The seed layer 101 is formed of a metal such as Cu, Ti, Au, Cr, Al, TiW, TiN, or Ni. The seed layer 101 is deposited using a conventional method such as chemical vapor deposition (CVD) or physical vapor deposition (PVD). The deposition method of the seed layer 101 would be known to one of ordinary skill in the art and thus the description thereof will be omitted.

In operation 365, electroplating is performed on the backside of the wafer on which the seed layer 321 is deposited so that a metal layer (or conductive layer) 331 is formed on the seed layer 321. The electroplating is performed using a typical electrolysis plating method or an A1 reflow method. The metal layer 331 is formed of a metal wiring having good electrical properties such as Cu, Ni, Au, Al, Ag, and the like on the entire backside surface of the wafer. Thus, the recess patterns 304 are completely filled with the metal layer 331. To expose the recess patterns 304 and the wafer substrate 301, the seed layer 321 and the metal layer 331 are planarized using polishing in operation 370. The planarization is performed using a chemical mechanical polishing (CMP) method, a back lap method, or a conventional polishing method.

After planarization, a lower insulating layer 341 is formed on the planarized backside of the wafer. Then, the insulating layer 341 is patterned using a polymer dielectric patterning method to expose an area OP2 where a metal wiring, that is, a through electrode, of a neighboring wafer will contact the wafer. The insulating layer 341 is formed of a polymer by spin coating, laminating, etc. The laminating includes placing a film formed of an insulating material between the adjacent wafers and treating the film with heat and/or pressure. The patterning of the insulating layer 341 is performed using a conventional method, and thus the detailed description thereof will be omitted.

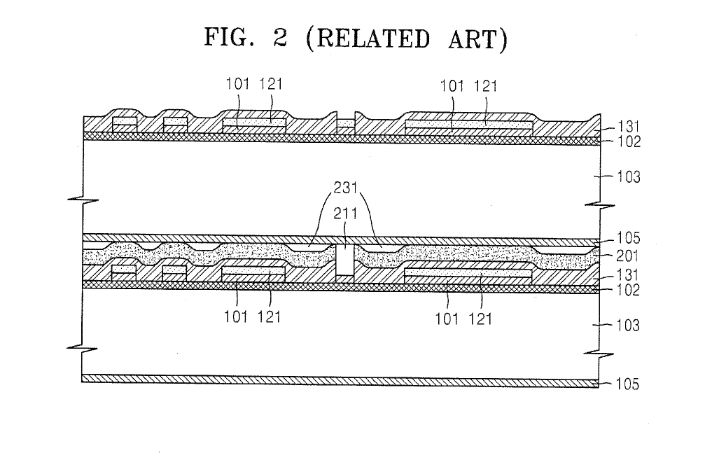

Accordingly, the metal layer wiring structure formed on the backside of the wafer does not have a curvature, and thus voids are not generated as in the conventional art shown in FIG. 2.

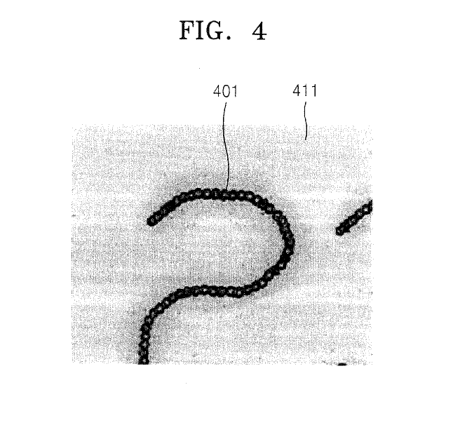

FIG. 4 is an image showing a recess pattern 401 formed on the backside of a wafer 411 using a laser as explained with reference to FIG. 3A.

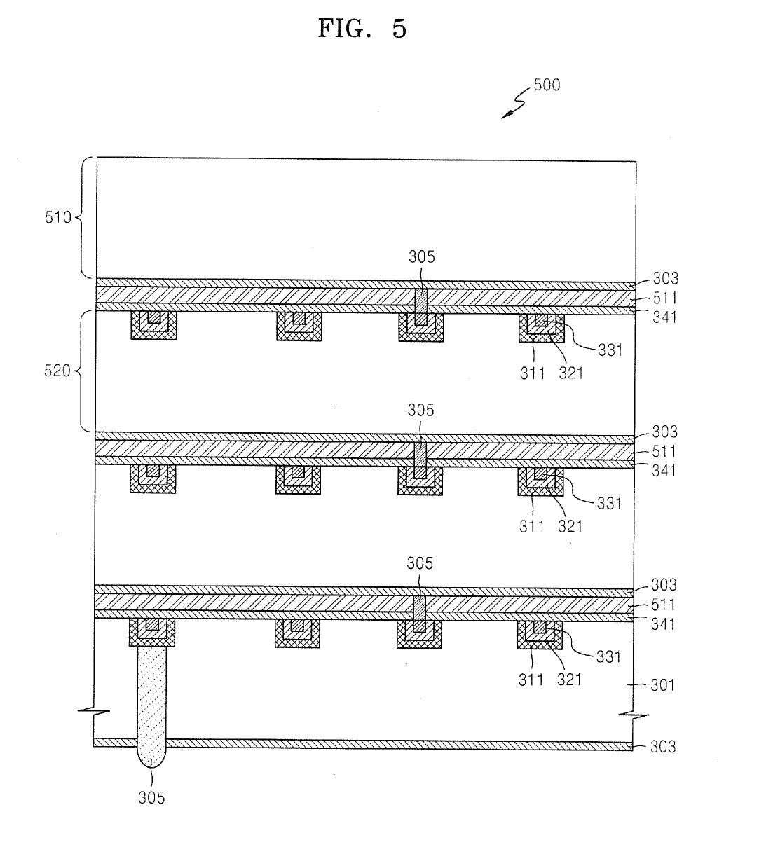

FIG. 5 illustrates a chip package stack 500 including a plurality of wafers 510, 520, etc formed as explained with reference to FIGS. 3A, 3B, and 3C.

Referring to FIG. 5, an adhesive layer 511 is placed between each of two adjacent wafers, as for example, between the first wafer 510 and the second wafer 520.

The adhesive layer 511 may be formed of, for example, epoxy. The adhesive layer 511 may be formed of any adhesive material that is conventionally used in chip stacking. The adhesive layer 511 may be coated on the lower part of the first wafer 510, and then the first wafer 510 is adhered to the second wafer 520. Alternatively, the adhesive layer 511 may be coated on the second wafer 520, and then the first wafer 510 is adhered to the second wafer 520. The process of coating the adhesive layer 511 to adhere the first wafer 510 and the second wafer 520 would be known to one of ordinary skill in the art.

In the chip package stack according to embodiments of the present invention, recess patterns are formed on a backside of a wafer, and the wafers including metal layers (for signal lines) filled in the recess patterns are stacked, thereby preventing the occurrence of voids. Accordingly, a lithography process as performed in a conventional method of forming a metal layer wiring structure, is not necessary, and thus the use of expensive equipment is not required and the manufacturing costs can be reduced. In addition, the process flow is reduced, thereby increasing yield.

According to an aspect of the present invention, there is provided a method of forming a wiring structure on a backside of a wafer, the method comprising: forming a plurality of recess patterns on a backside of the wafer; forming a passivation layer pattern on the backside of the wafer, the passivation layer pattern exposing an area corresponding to a through electrode; forming a conductive layer on the passivation layer pattern; planarizing the conductive layer to expose the recess patterns; and forming a lower insulating layer pattern on the planarized conductive layer, the lower insulating layer pattern exposing an area corresponding to a contact portion configured to contact another wafer, wherein the recess patterns are formed using a laser.

The forming of the conductive layer may comprise: forming a seed layer on the passivation layer; and forming a signal metal layer on the seed layer to fill the recess patterns.

The signal metal layer may be formed using an electroplating method or a reflow method.

Planarizing the conductive layer may comprise removing a portion of the passivation layer and a portion of the conductive layer that are formed in areas of the backside of the wafer that are not recessed.

According to another aspect of the present invention, there is provided a wiring structure comprising: a wafer; a plurality of recess patterns disposed on a backside of the wafer; and a lower insulating layer pattern disposed on the backside of the wafer, the lower insulating layer pattern exposing at least a portion of the recess patterns, wherein a passivation layer pattern is formed in the inside of the recess pattern portions in contact with the wafer, and a conductive material is disposed in the recess patterns.

The recess pattern portions may be formed by etching using a laser. The recess patterns may comprise: a seed layer formed on the passivation layer pattern; and a metal layer that is formed on the seed layer so as to fill the recessed portions.

The wiring structure may further comprise a through electrode formed in a vertical direction in at least one of the recess patterns.

According to another aspect of the present invention, there is provided a method of stacking a chip package including a plurality of wafers, the method comprising: forming a plurality of recess patterns on a backside of each of the wafers; forming a passivation layer pattern on the backside of each of the wafers, the passivation layer pattern exposing an area corresponding to a through electrode; forming a conductive layer on the passivation layer formed on each of the wafers; planarizing the conductive layers on each of the wafers so as to expose only the recess patterns; forming a lower insulating layer pattern on the planarized conductive layers of each of the wafers, the lower insulating layer pattern exposing an area corresponding to a contact portion; forming an adhesive layer on the lower insulating layer pattern of each of the wafers; and adhering the wafers to one another, wherein the recess patterns are formed using a laser.

The present invention has been particularly shown and described with reference to exemplary embodiments thereof. The terms used herein are for illustrative purpose of the present invention only and should not be construed to limit the meaning or the scope of the present invention as described in the claims. Thus, it will be understood by those of ordinary skill in the art that various changes in form and details may be made therein without departing from the spirit and scope of the present invention as defined by the following claims.

What is claimed is:

1. A method of forming a wiring structure on a backside of a wafer, the method comprising:
forming a plurality of recess patterns on the backside of the wafer;
forming a passivation layer pattern on the backside of the wafer, the passivation layer pattern exposing an area corresponding to a through electrode;
forming a conductive layer on the passivation layer;
planarizing the conductive layer to expose the recess patterns; and
forming a lower insulating layer pattern on the planarized conductive layer, the lower insulating layer pattern exposing an area corresponding to a contact portion configured to contact another wafer.

2. The method of claim 1, wherein the recess patterns are formed using a laser.

3. The method of claim 1, wherein the forming of the conductive layer comprises:
forming a seed layer on the passivation layer; and
forming a signal metal layer on the seed layer so as to fill the recess patterns.

4. The method of claim 3, wherein the signal metal layer is formed using an electroplating method or a reflow method, and wherein the seed layer is formed using a deposition method.

5. The method of claim 1, wherein planarizing the conductive layer comprises removing a portion of the passivation layer and a portion of the conductive layer that are formed in areas of the backside of the wafer that are not recessed.

6. The method of claim 5, wherein the planarizing of the conductive layer is performed using a chemical mechanical polishing (CMP) method, a back lap method, or a polishing method.

7. A wiring structure, comprising:
a wafer;
a plurality of recess patterns disposed on a backside of the wafer; and
a lower insulating layer pattern disposed on the backside of the wafer, the lower insulating layer pattern exposing at least a portion of the recess patterns,
wherein a passivation layer is disposed in the inside of the plurality of recess patterns in contact with the wafer, and a conductive material is disposed in the recess patterns.

8. The wiring structure of claim 7, wherein the recess patterns are formed by etching using a laser.

9. The wiring structure of claim 8, wherein the recess patterns comprise
a seed layer disposed on the passivation layer; and
a metal layer disposed on the seed layer so as to fill the recess patterns.

10. The wiring structure of claim 9, wherein the seed layer is formed using a deposition method.

11. The wiring structure of claim 8, further comprising a through electrode disposed in a vertical direction in at least one of the recess patterns.

12. The wiring structure of claim 8, wherein the lower insulating layer pattern is substantially planar.

13. A method of stacking a chip package including a plurality of wafers, the method comprising:
forming a plurality of recess patterns on a backside of each of the wafers using a laser;
forming a passivation layer pattern on the backside of each of the wafers, the passivation layer pattern exposing an area corresponding to a through electrode;
forming a conductive layer on the passivation layer pattern on each of the wafers;
planarizing the conductive layers on each of the wafers to expose the recess patterns;
forming a lower insulating layer pattern on the planarized conductive layers of each of the wafers, the lower insulating layer pattern exposing an area corresponding to a contact portion;
forming an adhesive layer on the lower insulating layer pattern of each of the wafers; and
adhering the wafers to one another.

14. The method of claim 13, wherein adhering the wafers comprises placing a through electrode of a first wafer in the contact portion of a second wafer so as to protrude toward a front surface of the second wafer.

15. The method of claim 14, wherein planarizing the conductive layers comprises removing portions of the passivation layer patterns and the conductive layers formed in areas of the backsides of the wafers that are not recessed.

16. The method of claim 14, wherein forming the conductive layers comprises:
forming a seed layer on the passivation layer pattern of each of the wafers; and
forming a metal layer on the seed layer of each of the wafers so as to fill the recess patterns.

17. The method of claim 16, wherein the metal layer patterns are formed using an electrolysis plating method or a reflow method.

18. A chip package stack structure, comprising:
a plurality of wafers stacked on top of each other, wherein an adhesive layer is disposed between neighboring wafers of the plurality of wafers such that a front side of one of the neighboring wafers is adhered to a backside of the other one of the neighboring wafers and wherein each of the plurality of wafers comprises:
a plurality of recess patterns disposed on a backside of the wafer; and
a lower insulating layer pattern disposed on the backside of the wafer, the lower insulating layer pattern exposing the recess patterns,
wherein a passivation layer is disposed in the inside of the recess patterns in each of the wafers, and the recess patterns are filled with a conductive material.

19. The chip package stack structure of claim 18, wherein the recess patterns are formed by laser etching.

20. The chip package stack structure of claim 19, wherein the recess patterns comprise:
a seed layer disposed on the passivation layer; and
a signal metal layer that is disposed on the seed layer so as to fill the recess patterns, the signal metal layer comprising a signal line.

21. The chip package stack structure of claim 19, wherein the lower insulating layer pattern of each of the wafers is substantially planar.

22. The chip package stack structure of claim 18, wherein each of the wafers further comprises a through electrode disposed in a vertical direction in at least one of the recess patterns.
